(19) United States
(12) Patent Application Publication
(10) Pub. No.: US 2026/0190881 A1
(43) Pub. Date: Jul. 2, 2026

(54) SEMICONDUCTOR DEVICE AND METHOD FOR FABRICATING THE SAME

(71) Applicants: TAIWAN SEMICONDUCTOR MANUFACTURING COMPANY, LTD, Hsinchu (TW); NATIONAL TAIWAN UNIVERSITY, TAIPEI (TW)

(72) Inventors: Ting-Yun WANG, Tainan City (TW); Miin-Jang CHEN, Taipei City (TW)

(73) Assignees: TAIWAN SEMICONDUCTOR MANUFACTURING COMPANY, LTD, Hsinchu (TW); NATIONAL TAIWAN UNIVERSITY, TAIPEI (TW)

(21) Appl. No.: 19/005,757

(22) Filed: Dec. 30, 2024

(51) Int. Cl. H01L 21/02; C23C 16/44; C23C 16/455

(52) U.S. Cl. CPC H10P 14/6339; C23C 16/4408; C23C 16/45536; C23C 16/45553; H10P 14/6319; H10P 14/69392

(57) ABSTRACT

A method for fabricating a semiconductor device is provided. The method includes depositing a ferroelectric layer over a non-insulating layer by an atomic layer deposition (ALD) process. The ferroelectric layer comprises a first metal element and a second metal element different from the first metal element. The ALD process comprises a plurality of cycles. Each of the cycles includes introducing a first precursor gas comprising the first metal element into a chamber; after introducing the first precursor gas into the chamber, introducing a second precursor gas comprising the second metal element into the chamber, such that a precursor surface layer comprising the first metal element and the second metal element is formed over the non-insulating layer; and performing an oxygen plasma treatment to convert the precursor surface layer into a monolayer of the ferroelectric layer.

### BACKGROUND

In the course of IC evolution, functional density (i.e., the number of interconnected devices per chip area) has increased while geometry size (i.e., the smallest component (or line) that can be created using a fabrication process) has decreased. This scaling down process provides benefits by increasing production efficiency and lowering associated costs. Such scaling-down also produces a relatively high power dissipation value, which may be addressed by using low power dissipation devices such as complementary metal-oxide-semiconductor (CMOS) devices. CMOS devices have been formed with a gate oxide and polysilicon gate electrode. There has been a desire to replace the gate oxide and polysilicon gate electrode with a high-k gate dielectric and metal gate electrode to improve device performance as feature sizes continue to decrease.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic view of a semiconductor device according to some embodiments of the present disclosure.

FIG. 1B is a schematic view of a semiconductor device according to some embodiments of the present disclosure.

FIG. 2 is an apparatus for an atomic layer deposition (ALD) process according to some embodiments of the present disclosure.

FIG. 3A shows pulses versus time in cycles of an ALD process according to some embodiments of the present disclosure.

FIG. 3B is a schematic view showing coverages of the multi-pulse deposition process in one of cycles of an ALD process according to some embodiments of the present disclosure.

FIG. 4A illustrates steps of one of the cycles of the ALD process of FIG. 3A.

FIG. 4B is a schematic view illustrating steps of the one of the cycles of the ALD process of FIG. 4A.

FIGS. 5A-5D are schematic views of the one of the cycles of the ALD process of FIG. 4A.

FIG. 6 is a structural formula of a zirconium-containing processor according to some embodiments of the present disclosure.

FIG. 7 is a structural formula of a hafnium-containing processor according to some embodiments of the present disclosure.

FIG. 8 is a graph illustrating experimental/simulation results showing a hysteresis loop of a memory cell according to some embodiments of the present disclosure.

FIG. 9 shows pulses versus time in cycles of an ALD process according to some embodiments of the present disclosure.

FIG. 10 is a graph illustrating experimental/simulation results showing atomic percent in three different devices according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The gate-all-around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

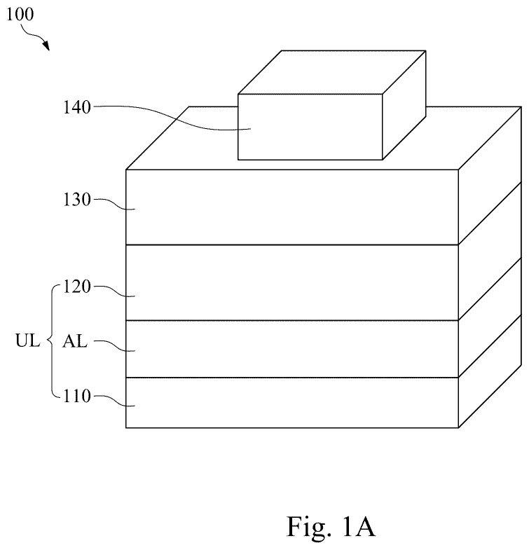

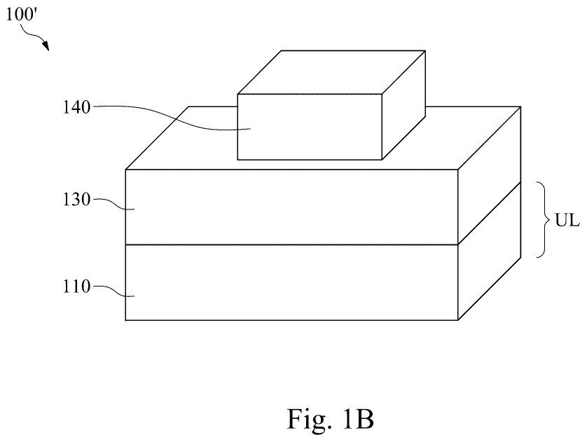

FIG. 1A is a schematic view of a semiconductor device 100 according to some embodiments of the present disclosure. The semiconductor device 100 may have a metal-ferroelectric-metal (MFM) stack, which may serve as a capacitor or a gate stack of a transistor. The semiconductor device 100 may include a substrate 110, an adhesive layer AL over the substrate 110, a bottom electrode 120 over the adhesive layer AL, a ferroelectric layer 130 over the bottom electrode 120, and a top electrode 140 over the ferroelectric layer 130. The substrate 110 may be a semiconductor substrate. For example, the substrate 110 may include semiconductor material, such as Si, Ge, GaN, SiC, GaAs, ZnO, InP, InGaAs, AlGaAs, SiGe, InGaN, AlN, IGZO, In₂O₃. The adhesive layer AL may include TiN. The bottom electrode 120 is deposited over the adhesive layer AL using CVD, PVD, plating, and/or other suitable processes. In some embodiments, the bottom electrode 120 may include metals, such as tungsten (W), aluminum (Al), titanium (Ti), titanium nitride (TiN), tantalum (Ta), tantalum nitride (TaN), cobalt (Co), copper (Cu), nickel (Ni), ruthenium (Ru), Chromium (Cr), combinations thereof, and/or other suitable materials. The bottom electrode 120 may have a higher electrical conductance than that of the adhesive layer AL. In some embodiments, the bottom electrode 120 may include indium tin oxide (ITO), LaSrMnO (LSMO)-based, strontium titanate (STO)-based, LaSrCoO (LSCO)-based, RuO₂, SrRuO₃, LaNiO₃, IrO₂, the like, or the combination thereof. After the formation/deposition of the bottom electrode 120, the ferroelectric layer 130 is deposited over the bottom electrode 120, follow by depositing the top electrode 140 over the ferroelectric layer 130.

The top electrode 140 may include metals, such as tungsten (W), aluminum (Al), titanium (Ti), titanium nitride (TiN), tantalum (Ta), tantalum nitride (TaN), cobalt (Co), copper (Cu), nickel (Ni), ruthenium (Ru), chromium (Cr), combinations thereof, and/or other suitable materials. The top electrode 140 may include indium tin oxide (ITO), LaSrMnO (LSMO)-based, strontium titanate (STO)-based, LaSrCoO (LSCO)-based, RuO₂, SrRuO₃, LaNiO₃, IrO₂, the like, or the combination thereof. The top electrode 140 may be deposited using CVD, PVD, plating, and/or other suitable processes.

FIG. 1B is a schematic view of a semiconductor device 100′ according to some embodiments of the present disclosure. Details of the present embodiments are similar to that of FIG. 1A, except that in the present embodiments, the semiconductor device 100′ may have a metal-oxide-semiconductor (MOS) structure, which may serve as a capacitor or a gate stack of a transistor. The semiconductor device 100′ may include a substrate 110, a ferroelectric layer 130 over the substrate 110, and a top electrode 140 over the ferroelectric layer 130. The ferroelectric layer 130 is deposited over the substrate 110, follow by depositing the top electrode 140 over the ferroelectric layer 130. Details of the substrate 110, the ferroelectric layer 130, and the top electrode 140 are similar to those illustrated in FIG. 1A, and therefore not repeated herein.

In the context, for better illustration, the layer below the ferroelectric layer 130 is denoted as an underlying layer UL. For example, in FIG. 1A, the underlying layer UL may include the bottom electrode 120, the adhesive layer AL, and the substrate 110, especially the bottom electrode 120. And, in FIG. 1B, the underlying layer UL may include the substrate 110. The underlying layer UL may be referred to as a non-insulating layer, which includes a material or component that does not impede the flow of electrical current. The non-insulating layer is a conductor layer or a semiconductor layer, rather than an insulator layer.

In present embodiments of the present disclosure, the ferroelectric layer 130 in FIGS. 1A and 1B may be deposited over the underlying layer UL (e.g., the bottom electrode 120 in FIG. 1A or the substrate 110 in FIG. 1B) by cyclic deposition, such as by atomic layer deposition (ALD). In the cyclic deposition, multiple cycles of precursors are flowed to a surface of the underlying layer UL to deposit a layer thereover. For example, for the ferroelectric layer 130 including Zr-doped HfO₂ (also referred to as hafnium zirconium oxide), each cycle includes providing a pulse of a zirconium-containing precursor, a pulse of a hafnium-containing precursor, and an exposure of an oxygen plasma (e.g., oxygen gas (O₂)), to form ZrO₂ and HfO₂.

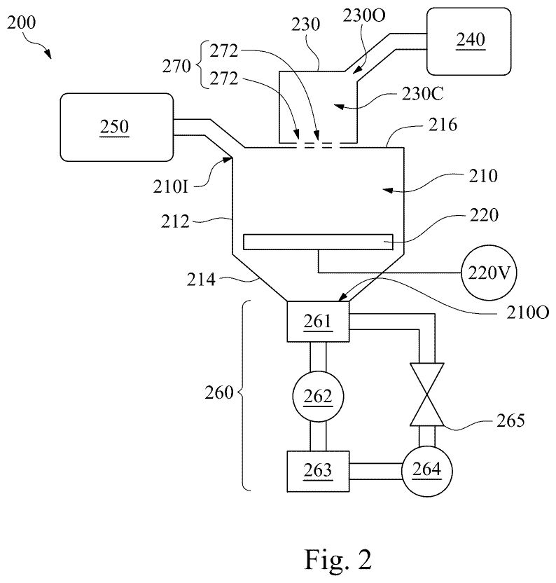

FIG. 2 is an apparatus 200 for ALD process according to some embodiments of the present disclosure. The apparatus 200 may include a processing chamber 210, a substrate support 220, a plasma source 230, a plasma gas supplier 240, a gas delivery system 250, and a gas evacuation system 260. In some embodiments, the substrate (e.g., the substrate 110 in FIGS. 1A and 1B) may be loaded into the chamber 210 for performing ALD, for depositing the ferroelectric layer 130 (referring to FIGS. 1A and 1B) over the underlying layer UL in FIGS. 1A and 1B.

In some embodiments, the processing chamber 210 includes chamber walls 212, chamber floor 214, and chamber ceiling 216. Inside the processing chamber 210 is a substrate support 220, on which substrate (e.g., the substrate 110 in FIGS. 1A and 1B) sits. The substrate support 220 may be a chunk. The substrate support 220 may be connected to a substrate voltage source 220V for substrate biasing. For example, the substrate support 220 provides an AC bias, a DC bias, or an AC bias superposed with a DC bias, to a substrate disposed thereon.

The plasma source 230 is near the processing chamber 210. The plasma source 230 may include a plasma generator (not shown) for generating a plasma. The plasma generator includes hardware (e.g., coils, electrodes, etc.) for producing a plasma, which may be an inductively coupled plasma, a capacitively coupled plasma, a microwave coupled plasma, etc. In some embodiments, the plasma source 230 is a remote/upper chamber plasma source that has an upper chamber 230C above and gaseous connected with the processing chamber 210. The remote/upper chamber plasma source can be a radiofrequency (rf) plasma source. The remote chamber plasma source 230 may generate a plasma within the upper chamber 230C, thereby reducing plasma-induced damage on the substrate surface. The remote chamber plasma source 230 has an inlet 230O fluidly connected with the plasma gas supplier 240 for providing gas to generate the remote plasma. The plasma gas supplier 240 may provide desired gases, such as N₂, H₂, O₂, inert gas (e.g., Ar, He/Ar, Ne, a mixture thereof), the like, or the combination thereof. In some other embodiments, other suitable plasma sources (e.g., inductively coupled plasma (ICP) source, transformer coupled plasma (TCP), hollow cathode plasma (HCP), and/or the substrate voltage source 220V) may be used to directly generate plasma within the processing chamber 210. In some embodiments, the substrate voltage source 220V may be used for generating and/or affecting the plasma in the processing chamber 210. The substrate bias and the upper chamber plasma can be controlled at voltage mode or power mode, together with an auto pressure control (APC) system, such that the precise control of the energy of incident electrons/ions on the substrate can be achieved.

The processing chamber 210 also includes an inlet 210I and an exhaust outlet 210O. The gas delivery system 250 and the gas evacuation system 260 are respectively fluidly connected to the inlet 210I and the exhaust outlet 210O. The gas delivery system 250 may provide desired precursors, such as zirconium-containing precursor (e.g., Tetrakis(dimethylamino)zirconium (IV)(TDMAZ)), hafnium-containing precursor (e.g., Tetrakis(dimethylamido)hafnium(IV)(TDMAH)), or the like. The gas evacuation system 260 may include various components, such as a trap 261, automatic pressure controller (APC) 262, turbomolecular pump (TMP) 263, a rotary pump (RP) 264, and a valve 265. These components are used to control the gas exhaustion.

In some embodiments, the apparatus 200 may further include a controller coupled to the plasma source 230, the substrate voltage source 220V, the plasma gas supplier 240, the gas delivery system 250, and the gas evacuation system 260. In some implementations, fewer or more components can be coupled to the controller. The controller may include a processor, a computer-readable medium, and an input/output (I/O) interface. The processor is used to perform calculations related to controlling at least some of the pressure, gas flow rates, plasma generation, substrate biasing, and other system parameters. A computer-readable medium (also referred to as a database or a memory) is coupled to the processor in order to store data used by the processor and other system elements. Using the processor, the memory, and the I/O interface, a user is able to operate the system to deposit material as described herein. The processor may include dedicated circuitry, ASICs, combinatorial logic, other programmable processors, combinations thereof, and the like. The processor can execute instructions and data. For example, the processor embodies at least part of the instructions for performing the method in accordance with the present disclosure in software, firmware and/or hardware. The memory may include a hard disk drive, flash memory, a floppy disk drive along with associated removable media, an optical drive, removable media cartridges, and other storage media. The memory can store instructions and data executed by the processor.

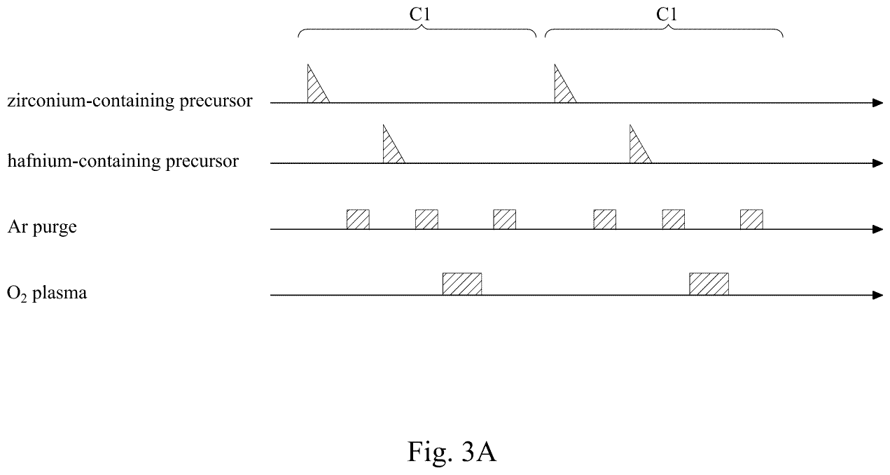

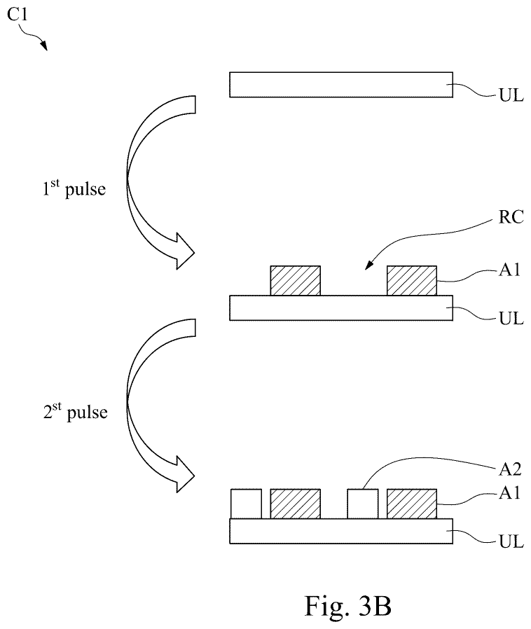

FIG. 3A shows pulses versus time in the cycles C1 of the ALD process according to some embodiments of the present disclosure. The ALD process includes plural repeated cycles C1, in which each cycle C1 includes the pulse of the zirconium-containing precursor (e.g., TDMAZ), the pulse of the hafnium-containing precursor (e.g., TDMAH), the exposure of an oxygen plasma (e.g., oxygen gas (O₂)), and plural purging steps (e.g., Ar purge). In some embodiments, a time duration of the oxygen plasma is greater than a time duration of the pulse of the zirconium-containing precursor and a time duration of the pulse of the hafnium-containing precursor.

In some embodiments of the present embodiments, in each cycle C1, for controlling a ratio of the zirconium and the hafnium in the ferroelectric layer 130, the pulse of the zirconium-containing precursor is followed by the pulse of the hafnium-containing precursor, and the exposure of the oxygen plasma is performed after the pulse of the zirconium-containing precursor and the pulse of the hafnium-containing precursor. In such embodiments, there is no exposure of the oxygen plasma performed between the pulse of the zirconium-containing precursor and the pulse of the hafnium-containing precursor. The implementation uses two consecutive precursor pluses (e.g., the pulse of the zirconium-containing precursor and the pulse of the hafnium-containing precursor) in a cycle C1, and can be referred to as a multi-pulse deposition process.

With this configuration, since the underlying layer UL is exposed to the pulse of the zirconium-containing precursor first, a zirconium-rich ferroelectric layer 130 is formed. For example, an atomic percent of the zirconium atoms in the ferroelectric layer 130 is greater than an atomic percent of the hafnium atoms in the ferroelectric layer 130. For example, the atomic percent of the zirconium atoms in the ferroelectric layer 130 is in a range from about 18% to about 25%, and the atomic percent of the hafnium atoms in the ferroelectric layer 130 is in a range from about 8% to about 13%. Stated differently, an atomic ratio of zirconium to hafnium is greater than 1. For example, the atomic ratio of zirconium to hafnium is in a range from about 1.5 to about 2.5, or even about 1.8 to about 2.2. In the context, the atomic ratio is a measure of the ratio of atoms of one kind to another kind, and atomic percent (or at. %) is the percentage of one kind of atom relative to the total number of atoms.

FIG. 3B is a schematic view showing coverages of the multi-pulse deposition process in one of cycles C1 of an ALD process according to some embodiments of the present disclosure. The first element of the first precursor may have a first coverage ratio (denoted as x in the context), and the second element of the second precursor may have a second coverage ratio (denoted as y in the context), in which x and y are in a range between 0 to 1. For example, the coverage ratio of the zirconium-containing precursor may be in a range from about 0.4 to about 0.6, and the coverage ratio of the hafnium-containing precursor may be in a range from about 0.4 to about 0.6. In the illustrated embodiments, the multi-pulse deposition process includes a first pulse of the first precursor followed by a second pulse of the second precursor, in which the first precursor includes first elements A1, and the second precursor includes second elements A2.

After the first pulse of the first precursor in the multi-pulse deposition process, the first element A1 in the first precursor may cover an area multiplied by x, leaving reaction sites RC in an area multiplied by (1−x). And, after the second pulse of the first precursor in the multi-pulse deposition process, the second element A2 in the second precursor may cover an area multiplied by y(1−x). Thus, since the underlying layer UL is exposed to the pulse of the first precursor first, an atomic percent of the first element A1 in the formed ferroelectric layer 130 is greater than an atomic percent of the second element A2 in the formed ferroelectric layer 130.

In the embodiments of FIG. 3A, the first element A1 is zirconium, and the first precursor can be TDMAZ or other zirconium-containing precursors, while the second element A2 is hafnium, and the second precursor can be TDMAH or other hafnium-containing precursors. Thus, an atomic percent of zirconium in the formed ferroelectric layer 130 is greater than an atomic percent of hafnium in the formed ferroelectric layer 130.

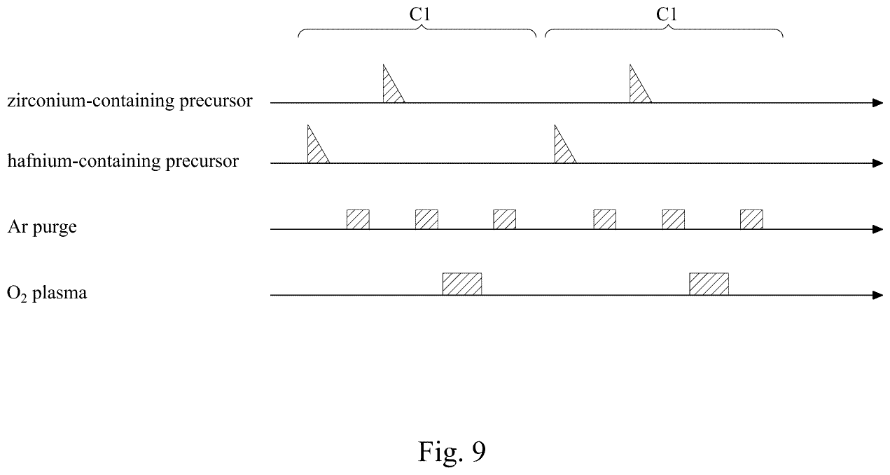

In the embodiments of FIG. 9 later, the first element A1 is hafnium, and the first precursor can be TDMAH or other hafnium-containing precursors, while the second element A2 is zirconium, and the second precursor can be TDMAZ or other zirconium-containing precursors. Thus, an atomic percent of hafnium in the formed ferroelectric layer 130 is greater than an atomic percent of zirconium in the formed ferroelectric layer 130.

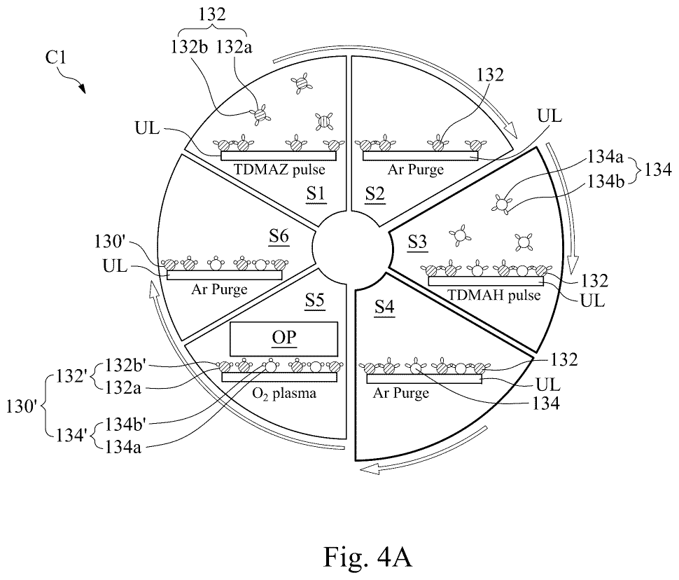

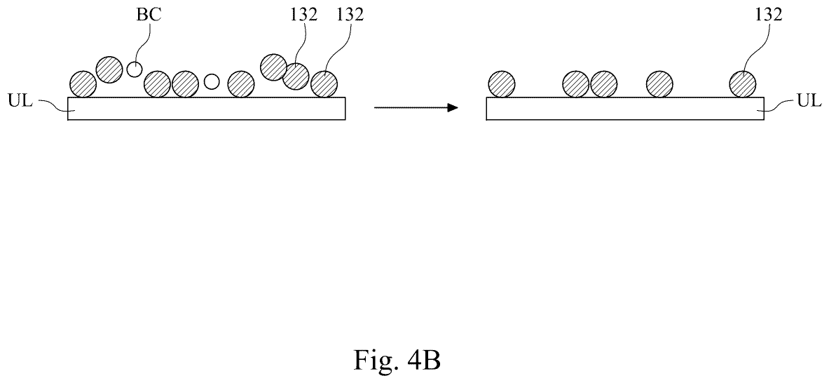

FIG. 4A illustrates steps of one of the cycles C1 of the ALD process of FIG. 3A. Each cycle C1 may include steps S1-S6, as the pulses shown in FIG. 3A. The steps S1-S6 is performed in a sequence and repeated as indicated by the arrows in FIG. 4A. It is understood that additional steps may be provided before, during, and after the steps S1-S6 shown in FIG. 4A, and some of the steps described below can be replaced or eliminated for additional embodiments of the method. The order of the operations/processes may be interchangeable. The steps S1-S6 of the cycle C1 may be performed in a range from about 100 Celsius degrees to about 400 Celsius degrees.

At step S1 of the cycle C1, where a pulse of a zirconium-containing precursor 132 is provided as in shown in FIG. 3A. The underlying layer UL (e.g., the bottom electrode 120 in FIG. 1A or the substrate 110 in FIG. 1B) is exposed to a zirconium-containing precursor 132. In some embodiments, the zirconium-containing precursor 132 may be Tetrakis(dimethylamino)zirconium (Zr(NMe₂)₄), Tetrakis(diethylamido)zirconium (Zr(NEt₂)₄), Tetrakis(ethylmethylamido)zirconium (Zr(NMeEt)₄), Cyclopentadienyl Tris(dimethylamino) Zirconium (CpZr(NMe₂)₃), Zirconium tetrachloride (ZrCl₄), the like, or the combination thereof. In some embodiments, the zirconium-containing precursor 132 may be illustrated as TDMAZ, for example, including zirconium atoms 132a and dimethylamino groups 132b. The zirconium atoms 132a of the zirconium-containing precursor 132 may chemically adsorb/bond a surface of a former layer (e.g., a former ferroelectric monolayer 130′). For example, the former ferroelectric monolayer 130′ may include zirconium atoms 132a, hafnium atoms 134a, and oxygen atoms 132b′ and 134b′ as shown at step S6. In some embodiments, during the zirconium-containing pulse, the gas delivery system 250 (referring to FIG. 2) may provide a mixture of the zirconium-containing precursor 132 and the Ar gas to the ALD chamber (e.g., the ALD chamber 210 in FIG. 2).

FIG. 4B is a schematic view illustrating steps S1 and S2 of the one of the cycles C1 of the ALD process of FIG. 4A. Reference is made to FIGS. 4A and 4B. At step S2 of the cycle C1, as the Ar purge step in FIG. 3A, the zirconium-containing precursor 132 is purged away from the ALD chamber. A purge process is performed to remove any remaining zirconium-containing precursor 132 and any byproducts from the ALD chamber (e.g., the ALD chamber 210 in FIG. 2). After the purge process, the layer of the chemically absorbed zirconium-containing precursor 132 (i.e., the zirconium precursor surface layer) is left on the surface. In some embodiments, for purging, the gas delivery system 250 (referring to FIG. 2) provides the Ar gas to the chamber 210 (referring to FIG. 2) at a faster rate than a flow rate of the Ar gas during the pulse of a zirconium-containing precursor at step S1.

Reference is made to FIG. 4A. At step S3 of the cycle C1, a pulse of a hafnium-containing precursor is provided as in shown in FIG. 3A. The underlying layer UL (e.g., the bottom electrode 120 in FIG. 1A or the substrate 110 in FIG. 1B) with the layer of the zirconium-containing precursor 132 (i.e., the precursor surface layer) is exposed to a hafnium-containing precursor 134. The hafnium-containing precursor 134 may include Tetrakis(dimethylamido)hafnium (Hf(NMe₂)₄), Tetrakis(diethylamido)hafnium (Hf(NEt₂)₄), Tetrakis(ethylmethylamido)hafnium (Hf(NMeEt)₄), Cyclopentadienyl Tris(dimethylamino) Hafnium (CpHf(NMe₂)₃), Hafnium tetrachloride (HfCl₄). In some embodiments, the hafnium-containing precursor 134 may be illustrated as TDMAH, for example, including hafnium atoms 134a and dimethylamino groups 134b. The hafnium atoms 134a of the hafnium-containing precursor 134 may chemically adsorb/bond a surface of a former layer (e.g., reaction sites on the former ferroelectric monolayer 130′). In some embodiments, during the hafnium-containing pulse, the gas delivery system 250 (referring to FIG. 2) may provide a mixture of the hafnium-containing precursor 134 and the Ar gas to the ALD chamber (e.g., the ALD chamber 210 in FIG. 2).

At step S4 of the cycle C1, as the Ar purge in FIG. 3A, the hafnium-containing precursor 134 is purged away from the ALD chamber. A purge process is performed to remove any remaining hafnium-containing precursor 134 and any byproducts from the ALD chamber (e.g., the ALD chamber 210 in FIG. 2). After the purge process, the layer of the hafnium-containing precursor 134 (i.e., the hafnium-containing precursor surface layer) is left on the surface. In some embodiments, for purging, the gas delivery system 250 (referring to FIG. 2) provides the Ar gas to the chamber 210 (referring to FIG. 2) at a faster rate than a flow rate of the Ar gas during the pulse of a hafnium-containing precursor at step S3. In some embodiments, with the zirconium-containing pulse and the hafnium-containing pulse, a precursor surface layer including the zirconium-containing precursor 132 and the hafnium-containing precursor 134 is formed.

At step S5 of the cycle C1, as the exposure of oxygen plasma in FIG. 4A, the oxygen plasma OP is provided to the ALD chamber. The oxygen plasma may be generated from oxygen-containing gases, such as O₂. With the oxygen plasma OP, the precursor surface layer that contains the zirconium-containing precursor 132 and the hafnium-containing precursor 134 at step S4 is oxidized into a Zr-doped HfO₂ layer 130′, which includes zirconium oxides 132′ and hafnium oxides 134′. For example, using the oxygen plasma OP, the dimethylamino groups 132b of the zirconium-containing precursor 132 and the dimethylamino groups 134b of the hafnium-containing precursor 134 are replaced with oxygen atoms 132b′ and 134b′, respectively. In some other embodiments, the exposure of oxygen plasma may be replaced by an oxidation process using oxygen-containing gases, such as O₂, H₂O, O₃, H₂O₂. By the oxidation process using the oxygen-containing gases, the precursor surface layer that contains the zirconium-containing precursor 132 and the hafnium-containing precursor 134 at step S4 can be oxidized into the Zr-doped HfO₂ layer 130′, without using a plasma.

At step S6 of the cycle C1, as the Ar purge in FIG. 4A, the oxygen plasma OP at step S5 is purged away from the ALD chamber. In some embodiments, for purging, the gas delivery system 250 (referring to FIG. 2) provides the Ar gas to the chamber 210 (referring to FIG. 2) at a faster rate than a flow rate of the Ar gas during the pulse of a zirconium-containing precursor at step S1 and/or a flow rate of the Ar gas during the pulse of a hafnium-containing precursor at step S3. By repeating the steps S1-S6, plural ferroelectric monolayer 130′ are formed one over another, thereby forming the ferroelectric layer 130 in FIG. 1.

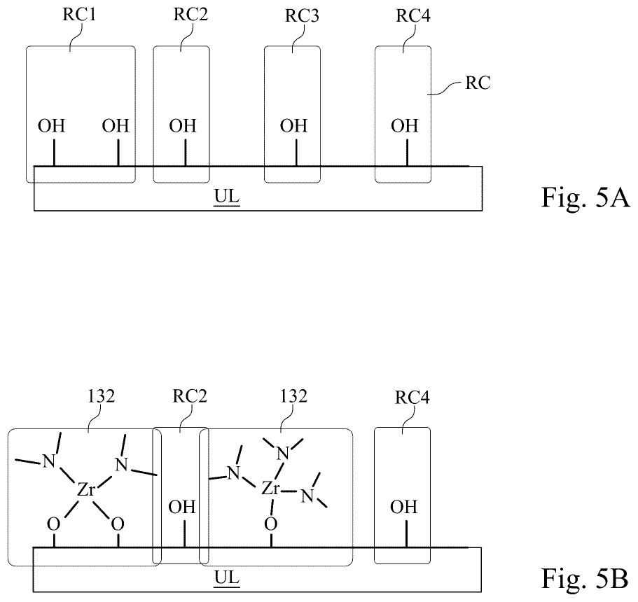

FIGS. 5A-5D are schematic views of the one of the cycles of the ALD process of FIG. 4A. In FIG. 5A, the reaction sites RC are located over the underlying layer UL (e.g., the bottom electrode 120 in FIG. 1A or the substrate 110 in FIG. 1B) (optionally with a former ferroelectric monolayer formed thereon). The reaction sites RC may include hydroxyl groups (—OH). For clear illustration, the reaction sites RC are illustrated as reaction sites RC1-RC4 in the drawings.

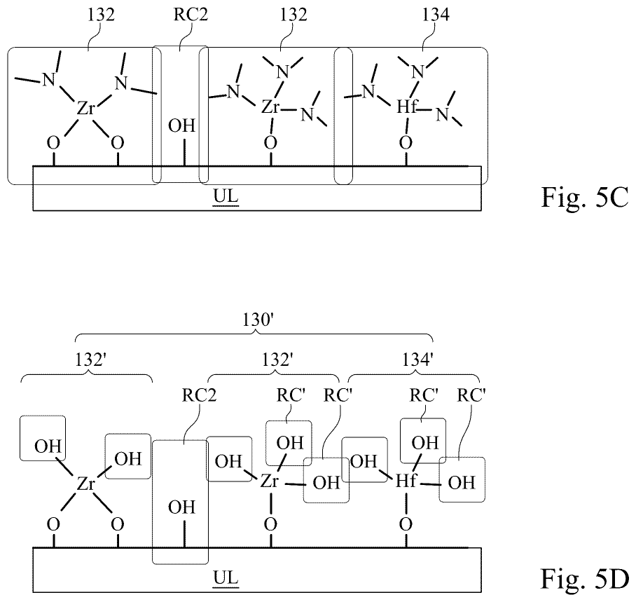

In FIG. 5B, during the pulse of the zirconium-containing precursor 132, the zirconium-containing precursors 132 reacts with the reaction sites RC1 and RC3. The zirconium-containing processor 132 is shown as a TDMAZ, which is illustrated in FIG. 6 later. The zirconium atoms of the zirconium-containing precursors 132 chemically adsorb/bond the hydroxyl groups (—OH) of the reaction sites RC1 and RC3. Due to the ALD coverage characteristics of the zirconium-containing precursors 132, the reaction sites RC2 and RC4 may not react with the zirconium-containing precursors 132. Stated differently, the reaction sites RC2 and RC4 remain available after the pulse of the zirconium-containing precursor 132.

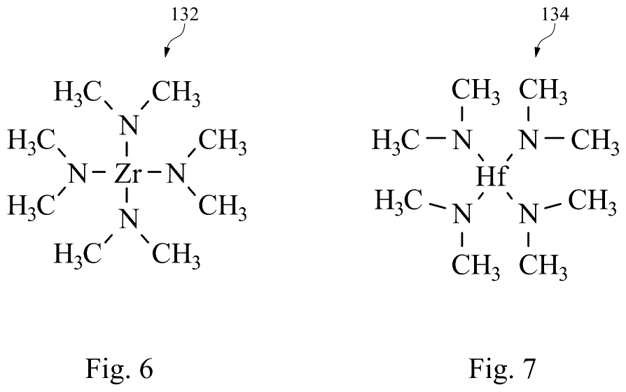

In FIG. 5C, during the pulse of the hafnium-containing precursor 134, the hafnium-containing precursors 134 reacts with the reaction site RC4. The hafnium-containing processor 134 is shown as a TDMAH, which is illustrated in FIG. 7 later. The hafnium atoms of the hafnium-containing precursors 134 chemically adsorb/bond the hydroxyl groups (-OH) of the reaction site RC4. Due to the ALD coverage of the hafnium-containing precursors 134, the reaction site RC2 may still not react with the hafnium-containing precursor 134. Stated differently, the reaction sites RC2 remain available after the pulse of the hafnium-containing precursor 134.

In FIG. 5D, with the oxygen plasma OP (referring to FIG. 4A), the zirconium-containing precursor 132 and the hafnium-containing precursor 134 are oxidized into zirconium oxides 132′ and hafnium oxides 134′, resulting the Zr-doped HfO₂ layer 130′. The zirconium oxides 132′ and hafnium oxides 134′ may include hydroxyl groups (—OH), which serve as reaction sites RC′ for next ALD cycle.

FIG. 6 is a structural formula of a zirconium-containing processor 132 according to some embodiments of the present disclosure. In FIG. 6, the zirconium-containing processor 132 is shown as a TDMAZ. TDMAZ is characterized by a central zirconium (Zr) atom surrounded by four dimethylamino (N(CH₃)₂) ligands. Each of the four dimethylamino groups acts as a ligand that coordinates to the zirconium through nitrogen atoms. The nitrogen atoms donate a pair of electrons to the metal center, establishing a covalent bond. Each N(CH₃)₂ ligand comprises a nitrogen atom bonded to two methyl groups (—CH₃). This configuration makes TDMAZ an example of a tetrahedral molecular geometry. The tetrahedral structure and organometallic nature of TDMAZ account for its reactivity and utility in processes such as atomic layer deposition (ALD), where it effectively delivers zirconium atoms for the formation of thin films like zirconium dioxide (ZrO₂).

FIG. 7 is a structural formula of a hafnium-containing processor 134 according to some embodiments of the present disclosure. In FIG. 7, the hafnium-containing processor 134 is shown as a TDMAH. TDMAH is characterized by a central hafnium (Hf) atom surrounded by four dimethylamino (N(CH₃)₂) ligands. Each of the four dimethylamino groups acts as a ligand that coordinates to the hafnium through nitrogen atoms. The nitrogen atoms donate a pair of electrons to the metal center, establishing a covalent bond. Each N(CH₃)₂ ligand comprises a nitrogen atom bonded to two methyl groups (—CH₃). This configuration makes TDMAH an example of a tetrahedral molecular geometry. The tetrahedral structure and organometallic nature of TDMAH account for its reactivity and utility in processes such as atomic layer deposition (ALD), where it effectively delivers hafnium atoms for the formation of thin films like hafnium dioxide (HfO₂).

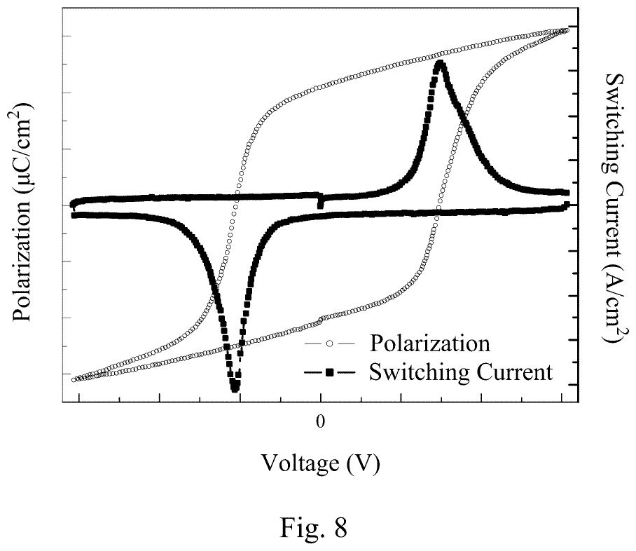

FIG. 8 is a graph illustrating experimental/simulation results showing a hysteresis loop of memory cells according to some embodiments of the present disclosure. The horizontal axis is voltage, the left vertical axis is polarization, and the right vertical axis is switching current. The values of double remnant polarization (2Pr, μC/cm²) can be extracted from the hysteresis curves of FIG. 8 at 0 volts on the vertical axis. This graph shows that, by depositing the ferroelectric monolayers 130′ with the multi-pulse ALD deposition process as illustrated in FIGS. 3A and 4A to form a ferroelectric layer 130 in FIG. 1, a large 2Pr in the ferroelectric layer 130 can be obtained, which is beneficial for data retention. For example, the 2Pr in the ferroelectric layer 130 is higher than 20 μC/cm². And, using the multi-pulse deposition process, the ferroelectric layer 130 (e.g., Zr-doped HfO₂ layer) in FIG. 1 can be formed with a thickness in a range from about 1 nanometer to about 50 nanometers, and maintains a good double remnant polarization (2Pr), e.g., greater than 20 μC/cm². It is evidenced from FIG. 8 that the ferroelectric layer 130 (e.g., Zr-doped HfO₂ layer) in FIG. 1A or 1B with higher Zr doping concentration shows a good ferroelectricity.

The ferroelectric layer 130 (e.g., Zr-doped HfO₂ layer) in FIG. 1A or 1B used in the experimental/simulation demonstrated a rapid and efficient response to the applied electric field. This quick response is crucial for high-speed memory applications, suggesting that the material can effectively meet the demands of advanced computing devices. Moreover, the observed switching current was robust, indicating strong and stable polarization states.

FIG. 9 shows pulses versus time in cycles of an ALD process according to some embodiments of the present disclosure. Details of the present embodiments are similar to those of the embodiments in FIG. 3A, except that the pulse of the zirconium-containing precursor is performed after the pulse of the hafnium-containing precursor. Similarly, in the present embodiments, the exposure of the oxygen plasma is performed after the pulse of the zirconium-containing precursor and the pulse of the hafnium-containing precursor, and no exposure of the oxygen plasma is performed between the pulse of the hafnium-containing precursor and the pulse of the zirconium-containing precursor. In the present embodiments, since the underlying layer UL (e.g., the bottom electrode 120 in FIG. 1A or the substrate 110 in FIG. 1B) is exposed to the pulse of the hafnium-containing precursor first, a hafnium-rich ferroelectric layer 130 is formed.

For example, an atomic percent of the hafnium atoms in the ferroelectric layer 130 is greater than an atomic percent of the zirconium atoms in the ferroelectric layer 130. For example, the atomic percent of the zirconium atoms in the ferroelectric layer 130 is in a range from about 8% to about 15%, and the atomic percent of the hafnium atoms in the ferroelectric layer 130 is in a range from about 15% to about 25%. Stated differently, an atomic ratio of zirconium to hafnium in the ferroelectric layer 130 is less than 1. For example, the atomic ratio of zirconium to hafnium in the ferroelectric layer 130 is in a range from about 0.3 to about 0.8.

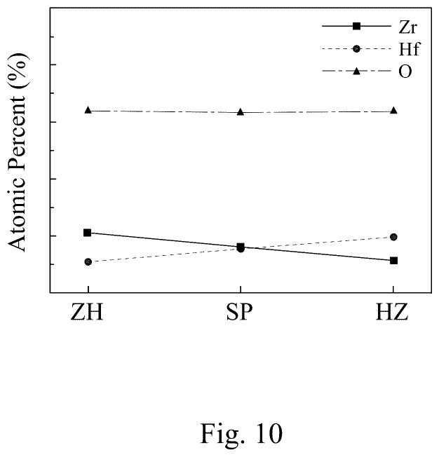

FIG. 10 is a graph illustrating experimental/simulation results showing atomic percent in three different devices according to some embodiments of the present disclosure. The vertical axis is the atomic percent (%). The sample “ZH” indicates a zirconium-rich ferroelectric layer formed by repeating cycles including a multi-pulse deposition (a zirconium-containing precursor pulse followed by a hafnium-containing precursor pulse) as shown in FIG. 3A. The sample “HZ” indicates a hafnium-rich ferroelectric layer formed by repeating cycles including a multi-pulse deposition (a hafnium-containing precursor pulse followed by a zirconium-containing precursor pulse) as shown in FIG. 10. The sample “SP” indicates a ferroelectric layer formed by repeating cycles including a single pulse deposition of hafnium oxide and a single pulse deposition of zirconium oxide, in which the hafnium-containing precursor and the zirconium-containing precursor are oxidized at different steps to form the hafnium oxide monolayer and the zirconium oxide monolayer, respectively.

It is evidenced from FIG. 10 that the oxygen atomic percentage keeps substantially unchanged in the samples “ZH”, “SP”, and “HZ.” The first precursor has a much large influence to the atomic percentage in the ferroelectric layer. For example, the sample “ZH” has a zirconium-to-hafnium ratio greater than 1, and the sample “HZ” has a zirconium-to-hafnium ratio less than 1. Thus, by controlling a pulsing sequence in the multi-pulse ALD process, a ratio between Zr and Hf can be adjusted for obtaining a better 2Pr, especially for sub-10 nm thin films.

Based on the above discussions, it can be seen that the present disclosure offers advantages to the HKMG devices. It is understood, however, that other embodiments may offer additional advantages, and not all advantages are necessarily disclosed herein, and that no particular advantage is required for all embodiments. One advantage is that Zr and Hf precursors are introduced into an ALD chamber with a pulsing sequence in the multi-pulse ALD process, thereby adjusting a ratio between Zr and Hf for thin film, especially for sub-10 nm thin films. Another advantage is that the multi-pulse ALD process can bring in a uniform doping distribution along the film thickness. Still another advantage is that the ferroelectric film can be deposited with a high surface coverage.

According to some embodiments of the present disclosure, a method for fabricating a semiconductor device is provided. The method includes depositing a ferroelectric layer over a non-insulating layer by an atomic layer deposition (ALD) process, wherein the ferroelectric layer comprises a first metal element and a second metal element different from the first metal element, and the ALD process comprises a plurality of cycles. Each of the cycles includes introducing a first precursor gas comprising the first metal element into a chamber; after introducing the first precursor gas into the chamber, introducing a second precursor gas comprising the second metal element into the chamber, wherein introducing the first precursor gas into the chamber and introducing the second precursor gas into the chamber are performed such that a precursor surface layer comprising the first metal element and the second metal element is formed over the non-insulating layer; and performing an oxygen plasma treatment to convert the precursor surface layer into a monolayer of the ferroelectric layer.

According to some embodiments of the present disclosure, a method for fabricating a semiconductor device is provided. The method includes depositing a ferroelectric layer over a non-insulating layer by an atomic layer deposition (ALD) process in an ALD chamber. The ALD process comprises at least a cycle. The cycle comprises exposing the non-insulating layer to a first metal-containing precursor; after exposing the non-insulating layer to the first metal-containing precursor, exposing the non-insulating layer to a second metal-containing precursor, wherein the second metal-containing precursor comprises a second metal element different from a first metal element of the first metal-containing precursor; and exposing the non-insulating layer to an oxygen plasma after exposing the non-insulating layer to the second metal-containing precursor.

According to some embodiments of the present disclosure, a semiconductor device includes a non-insulating layer, a hafnium zirconium oxide layer over the non-insulating layer, and a top electrode over the hafnium zirconium oxide layer. An atomic ratio of zirconium to hafnium in the hafnium zirconium oxide layer is greater than 1, and a double remnant polarization of the hafnium zirconium oxide layer is greater than 20 μC/cm².

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for fabricating a semiconductor device, comprising:
depositing a ferroelectric layer over a non-insulating layer by an atomic layer deposition (ALD) process, wherein the ferroelectric layer comprises a first metal element and a second metal element different from the first metal element, and the ALD process comprises a plurality of cycles, and each of the cycles comprises:
introducing a first precursor gas comprising the first metal element into a chamber;
after introducing the first precursor gas into the chamber, introducing a second precursor gas comprising the second metal element into the chamber, wherein introducing the first precursor gas into the chamber and introducing the second precursor gas into the chamber are performed such that a precursor surface layer comprising the first metal element and the second metal element is formed over the non-insulating layer; and
performing an oxygen plasma treatment to convert the precursor surface layer into a monolayer of the ferroelectric layer.

2. The method of claim 1, wherein each of the cycles of the ALD process further comprises:
purging a remaining portion of the first precursor gas away from the chamber prior to introducing the second precursor gas into the chamber.

3. The method of claim 1, wherein each of the cycles of the ALD process further comprises:
purging a remaining portion of the second precursor gas away from the chamber prior to the oxygen plasma treatment.

4. The method of claim 1, wherein the oxygen plasma treatment is performed such that the precursor surface layer is oxidized into a metal oxide comprising the first metal element and the second metal element.

5. The method of claim 1, wherein the oxygen plasma treatment is performed such that the ferroelectric layer comprises a plurality of hydroxyl groups.

6. The method of claim 1, wherein the first metal element is zirconium, and the second metal element is hafnium.

7. The method of claim 1, wherein the first metal element is hafnium, and the second metal element is zirconium.

8. The method of claim 1, wherein introducing the first precursor gas comprising the first metal element into the chamber is performed such that a first precursor comprising the first metal element is formed over the non-insulating layer, and introducing the second precursor gas comprising the second metal element into the chamber is performed when the first precursor is unoxidized.

9. A method for fabricating a semiconductor device, comprising:
depositing a ferroelectric layer over a non-insulating layer by an ALD process in an ALD chamber, and the ALD process comprises at least a cycle comprising:
exposing the non-insulating layer to a first metal-containing precursor;
after exposing the non-insulating layer to the first metal-containing precursor, exposing the non-insulating layer to a second metal-containing precursor, wherein the second metal-containing precursor comprises a second metal element different from a first metal element of the first metal-containing precursor; and
exposing the non-insulating layer to an oxygen plasma after exposing the non-insulating layer to the second metal-containing precursor.

10. The method of claim 9, wherein the cycle further comprises:
purging the ALD chamber after exposing the non-insulating layer to the first metal-containing precursor and before exposing the non-insulating layer to the second metal-containing precursor.

11. The method of claim 9, wherein the cycle further comprises:
purging the ALD chamber after exposing the non-insulating layer to the second metal-containing precursor and before exposing the non-insulating layer to the oxygen plasma.

12. The method of claim 9, wherein the cycle further comprises:
purging the ALD chamber after exposing the non-insulating layer to the oxygen plasma.

13. The method of claim 9, wherein the first metal element is zirconium, and the second metal element is hafnium.

14. The method of claim 9, wherein depositing the ferroelectric layer is performed such that an atomic percent of the first metal element in the deposited ferroelectric layer is greater than an atomic percent of the second metal element in the deposited ferroelectric layer.

15. The method of claim 9, further comprising:
forming a top electrode over the ferroelectric layer after depositing the ferroelectric layer.

16. A semiconductor device, comprising:
a non-insulating layer;
a hafnium zirconium oxide layer over the non-insulating layer, wherein an atomic ratio of zirconium to hafnium in the hafnium zirconium oxide layer is greater than 1, and a double remnant polarization of the hafnium zirconium oxide layer is greater than 20 μC/cm²; and
a top electrode over the hafnium zirconium oxide layer.

17. The semiconductor device of claim 16, wherein the atomic ratio of zirconium to hafnium in the hafnium zirconium oxide layer is in a range from about 1.5 to about 2.5.

18. The semiconductor device of claim 16, wherein a zirconium atomic percent of the hafnium zirconium oxide layer is in a range from about 18% to about 25%.

19. The semiconductor device of claim 16, wherein a hafnium atomic percent of the hafnium zirconium oxide layer is in a range from about 8% to about 13%.

20. The semiconductor device of claim 16, wherein the hafnium zirconium oxide layer has a thickness in a range from about 1 nanometer to about 50 nanometers.
